(19) United States
(12) Patent Application Publication
(10) Pub. No.: US 2019/0378733 A1
(43) Pub. Date: Dec. 12, 2019

(54) METHOD OF MANUFACTURING SEMICONDUCTOR DEVICE AND CLEANING APPARATUS

(71) Applicant: RENESAS ELECTRONICS CORPORATION, Tokyo (JP)

(72) Inventors: Yohei HAMAGUCHI, Ibaraki (JP); Shin AOYAMA, Ibaraki (JP); Tetsuya TAYAMA, Ibaraki (JP)

(21) Appl. No.: 16/410,648

(22) Filed: May 13, 2019

(30) Foreign Application Priority Data
Jun. 12, 2018 (JP) 2018-111781

(51) Int. Cl. H01L 21/67; H02K 11/27; H01L 21/02; H01L 21/66

(52) U.S. Cl. CPC H01L 21/67253; H02K 11/27; H01L 21/02065; H01L 22/14; H01L 21/02074; H01L 21/02071; H01L 21/67046; H01L 21/02063

(57) ABSTRACT

The method of manufacturing a semiconductor device according to the embodiment includes a step of performing cleaning. The cleaning step includes a step of preparing a cleaning apparatus having a first rotation mechanism including a first motor, a second rotation mechanism including a second motor, a second central shaft, and a cylindrical roller brush including an outer peripheral surface; a step of rotating the semiconductor wafer around the first central axis by the first rotation mechanism; and a step of rotating the roller brush around the second central axis by the second rotation mechanism and contacting the outer peripheral surface with the surface. An abnormality in the cleaning step is detected based on the current output from the second motor.

### CROSS-REFERENCE TO RELATED APPLICATIONS

The disclosure of Japanese Patent Application No. 2018-111781 filed on Jun. 12, 2018 including the specification, drawings and abstract is incorporated herein by reference in its entirety.

### BACKGROUND

The present invention relates to a method of manufacturing a semiconductor device and a cleaning apparatus.

Conventionally, a CMP apparatus described in Japanese Patent Application Laid-Open No. 2001-85377 (Patent Document 1) has been known. The CMP apparatus disclosed in Patent Document 1 includes a head that rotates in a state where a semiconductor wafer is mounted thereon, and a photoelectric sensor attached to the head. A notch is formed to the semiconductor wafer. The CMP apparatus described in Patent Document 1 detects whether the notch of the semiconductor wafer has passed over the photoelectric sensor, thereby detecting the rotational state of the semiconductor wafer.

A servo unit described in Japanese Patent Application Laid-Open No. 2012-103032 (Patent Document 2) has been conventionally known. The servo unit described in Patent Document 2 includes a motor and an encoder. In the servo unit described in Patent Document 2, the rotation of the motor is detected by an encoder.

### SUMMARY

The cleaning apparatus is used in an environment in which a liquid such as water or acid is scattered. In such an environment, it is difficult to arrange a photoelectric sensor as described in Patent Document 1. This is because the photoelectric sensor does not function due to the influence of liquid such as water or acid scattered. Further, in the cleaning apparatus, the rotation of the motor is transmitted to the semiconductor wafer via the rotation mechanism, so that the semiconductor wafer rotates. Therefore, even if the motor rotates normally, the rotation of the motor is not transmitted to the semiconductor wafer due to the abnormality of the other portions of the rotation mechanism, and as a result, the semiconductor wafer may not rotate normally. Therefore, in the method of detecting the rotation of the motor as described in Patent Document 2, it may not be possible to detect whether the rotation of the semiconductor wafer is normal or not.

Other objects and novel features will become apparent from the description of this specification and the accompanying drawings.

The method of manufacturing a semiconductor device according to an embodiment includes a step of preparing a semiconductor wafer having a front surface and a first central axis perpendicular to the front surface and having an interlayer insulating film formed on the surface, a step of forming a groove in the interlayer insulating film, a step of embedding a conductive material in the groove, a step of removing the conductive material protruding from the groove by chemical mechanical polishing, and a step of cleaning the semiconductor wafer.

The cleaning step includes a step of preparing a cleaning apparatus having a first rotation mechanism including a first motor, a second rotation mechanism including a second motor, and a roller brush including a second central axis and an outer peripheral surface; a step of rotating the semiconductor wafer around the first central axis by the first rotation mechanism; and a step of rotating the roller brush around the second central axis by the second rotation mechanism and contacting the outer peripheral surface with the front surface. In the manufacturing method of the semiconductor device according to the embodiment, an abnormality in the cleaning step is detected based on the output of the current from the second motor.

In accordance with some embodiments of the method of manufacturing a semiconductor device, it is possible to more accurately detect whether the step of cleaning the semiconductor wafer is normally performed.

### BRIEF DESCRIPTION OF THE DRAWINGS

FIG. 1 is a process diagram illustrating a method of manufacturing a semiconductor device according to a first embodiment;

FIG. 2 is a cross-sectional view of the semiconductor wafer preparation process S1 according to a method of manufacturing a semiconductor device of the first embodiment;

FIG. 3 is a cross-sectional view illustrating a groove forming step S2 according to a method of manufacturing a semiconductor device of the first embodiment;

FIG. 4 is a cross-sectional view of a process S3 for implanting a conductive material in a method of manufacturing a semiconductor device of the first embodiment;

FIG. 5 is a cross-sectional view of a chemical mechanical polishing process S4 according to a method of manufacturing a semiconductor device of the first embodiment;

FIG. 6 is a schematic diagram of a cleaning apparatus CE1 used in a method of manufacturing a semiconductor apparatus according of the first embodiment;

FIG. 7 is a graph showing the current output from the motor M2 when the rotating mechanism RM1 is normal in the cleaning process S5 of the method of manufacturing the semiconductor device of the first embodiment;

FIG. 8 is a graph showing the current output from the motor M2 when the rotating mechanism RM1 is abnormal in the cleaning process S5 of the method of manufacturing the semiconductor device of the first embodiment;

FIG. 9 is a schematic diagram illustrating a positional relationship between a roller brush RB and a semiconductor wafer WF in a method of manufacturing a semiconductor device of the first embodiment;

FIG. 10 is a graph showing a relation between v_{rb} and y in the manufacturing method of the semiconductor device of the first embodiment;

FIG. 11 is a graph showing the relation between v_{rb} and y when the ω_{w} is relatively large in the method of manufacturing a semiconductor device of the first embodiment;

FIG. 12 is a graph showing the relation between the v_{rb} and y when the ω_{w} is relatively small in the method of manufacturing a semiconductor device of the first embodiment;

FIG. 13 is a graph showing the relationship between the difference between the first current and the second current and the rotational speed of the semiconductor wafer WF in the method of manufacturing the semiconductor device of the first embodiment;

FIG. 14 is a process diagram illustrating a method of manufacturing a semiconductor device of a second embodiment;

FIG. 15 is a cross-sectional view of a semiconductor wafer preparation process S6 according to a method of manufacturing a semiconductor device of the second embodiment;

FIG. 16 is a sectional view illustrating a conductive film forming process S7 according to a method of manufacturing a semiconductor device of the second embodiment;

FIG. 17 is a schematic diagram of a cleaning apparatus CE2 used in a method of manufacturing a semiconductor apparatus of the second embodiment;

FIG. 18 is a cross-sectional view illustrating a photoresist coating process S9 according to a method of manufacturing a semiconductor device of the second embodiment;

FIG. 19 is a cross-sectional view of a photolithography process S10 according to a method of manufacturing a semiconductor device of the second embodiment;

FIG. 20 is a cross-sectional view of an etching process S11 according to a method of manufacturing a semiconductor device of the second embodiment;

FIG. 21 is a graph showing the current output from the motor M4 in the cleaning step S5 of the method of manufacturing a semiconductor device of the second embodiment;

FIG. 22 is a graph illustrating the relationship between the fourth current and the rotational speed of the semiconductor wafer WF in the method of manufacturing a semiconductor device of the second embodiment;

FIG. 23 is a schematic diagram illustrating a positional relationship between a pen-type brush PB and a semiconductor wafer WF in a method of manufacturing a semiconductor device of the second embodiment;

FIG. 24 is a graph illustrating a simulation result of the relationship between the rotational speed of the semiconductor wafer WF and the torque acting on the pen-type brush PB in a method of manufacturing a semiconductor device of the second embodiment;

FIG. 25 is a sectional view illustrating a groove forming process S2 according to a method of manufacturing a semiconductor device of the third embodiment;

FIG. 26 is a cross-sectional view of a process S3 for implanting a conductive material in a method of manufacturing a semiconductor device of the third embodiment;

FIG. 27 is a sectional view of a chemical mechanical polishing process S4 according to a method of manufacturing a semiconductor device of the third embodiment;

FIG. 28 is a schematic diagram of a cleaning apparatus CE3 used in a method for manufacturing a semiconductor apparatus of the fourth embodiment;

FIG. 29A and FIG. 29B are a graph showing a current output from a motor M1 in a cleaning step S5 of the method of manufacturing a semiconductor device of the fourth embodiment; and

FIG. 30 is a graph showing the relationship between the difference between the fifth current and the sixth current and the rotational speed of the roller brush RB in the method of manufacturing the semiconductor device of the fourth embodiment.

### DETAILED DESCRIPTION

Detailed description of the invention will be described with reference to the accompanying drawings. In all the drawings, the same and corresponding portions are denoted by the same reference numerals, and redundant description will not be repeated

Following, a method of a manufacturing a semiconductor device according to a first embodiment will be described.

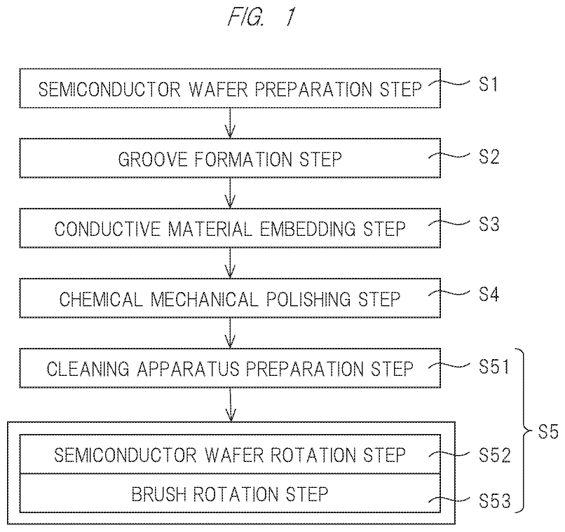

As shown in FIG. 1, the method of manufacturing a semiconductor device according to the first embodiment includes a semiconductor wafer preparation step S1, a groove formation step S2, a conductive material embedding step S3, a chemical mechanical polishing step S4, and a cleaning step S5.

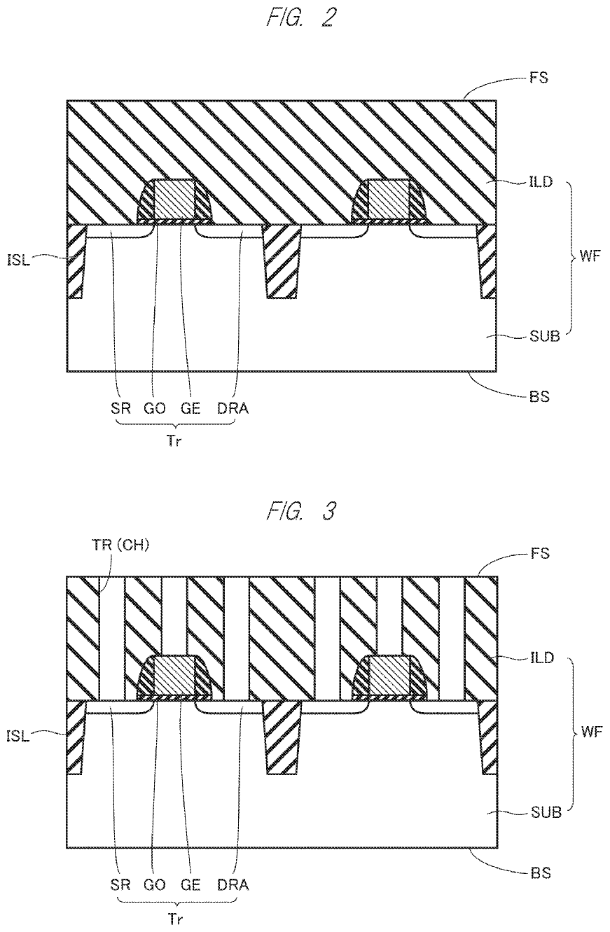

As shown in FIG. 2, in the semiconductor wafer preparation step S1, a semiconductor wafer WF is prepared. The semiconductor wafer WF has a semiconductor substrate SUB and an interlayer insulating film ILD. The semiconductor wafer WF has a front surface FS and a back surface BS. The semiconductor substrate SUB has a first surface and a second surface. The second surface is an opposite surface of the first surface.

The interlayer insulating film ILD is formed on the surface FS side of the semiconductor wafer WF. The interlayer insulating film ILD is formed on the first surface of the semiconductor substrate SUB. The interlayer insulating film ILD is formed of, for example, silicon oxide (SiO₂). The semiconductor substrate SUB is formed of, for example, single crystal silicon (Si).

A transistor Tr is formed in the semiconductor wafer WF. The transistor Tr includes a source region SR, a drain region DRA, a well region WR (not shown in the figure), a gate insulating film GO, and a gate electrode GE. The source region SR and the drain region DRA are formed on the first surface of the semiconductor substrate SUB. The well region WR is formed on the first surface of the semiconductor substrate SUB so as to surround the source region SR and the drain region.

The gate insulating film GO is formed on the well region WR sandwiched between the source region SR and the drain region DRA. The gate electrode GE is formed on the gate insulating film GO. Each transistor Tr is insulated and separated from each other by an element isolation film ISL. The element isolation film ISL is formed on the first surface of the semiconductor substrate SUB. The isolation film ISL is, for example, an Shallow Groove Isolation.

The gate insulating film GO is formed of, for example, silicon oxide. The gate electrode GE is formed of, for example, polycrystalline silicon doped with an impurity. The element isolation film ISL is formed of, for example, silicon oxide. The conductivity types of the source region SR and the drain region DRA are opposite to the conductivity types of the well region WR.

The semiconductor wafer WF is prepared by a conventionally known method. The source region SR, the drain region DRA, and the well region WR are formed by, for example, an ion implantation method. The gate insulating film GO is formed by, for example, thermal oxidation. The gate electrode GE is formed by forming a film of a material constituting the gate electrode GE by CVD (Chemical Vapor Deposition) or the like and patterning the material by photolithography and etching. The interlayer insulating film ILD is formed, for example, by forming a material constituting the interlayer insulating film ILD by CVD or the like and planarizing the material by Chemical Mechanical Polishing (CMP).

In the groove forming step S2, as shown in FIG. 3, a groove TR is formed in the interlayer insulating film ILD. In the method of manufacturing a semiconductor device according to the first embodiment, the groove TR is a contact hole CH. The contact hole CH is located on the source region SR, the drain region DRA, and the gate electrode GE. The groove TR is formed, for example, by anisotropically etching the interlayer insulating film ILD by RIE or the like.

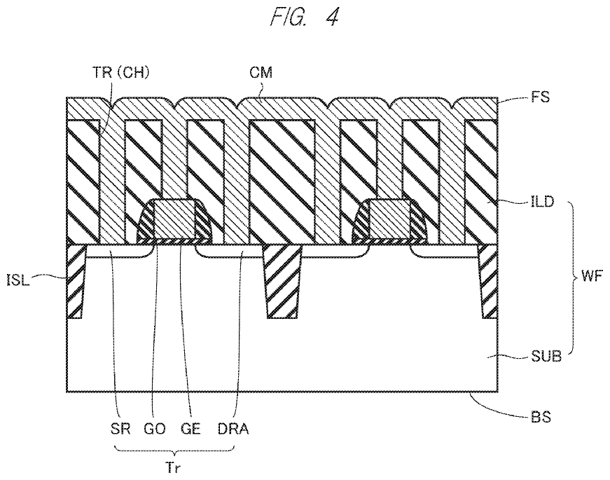

In the conductive material filling step S3, as shown in FIG. 4, the conductive material CM is filled in the contact hole CH. The conductive material CM is, for example, a material constituting the contact plug CP. The conductive material CM is, for example, tungsten (W). The conductive material CM is buried in the contact hole CH by, for example, CVD or the like.

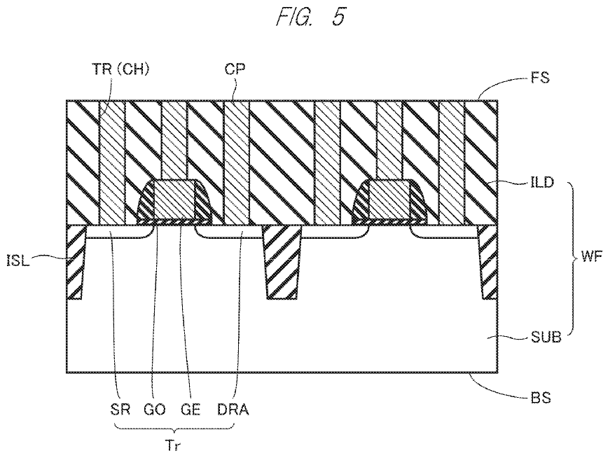

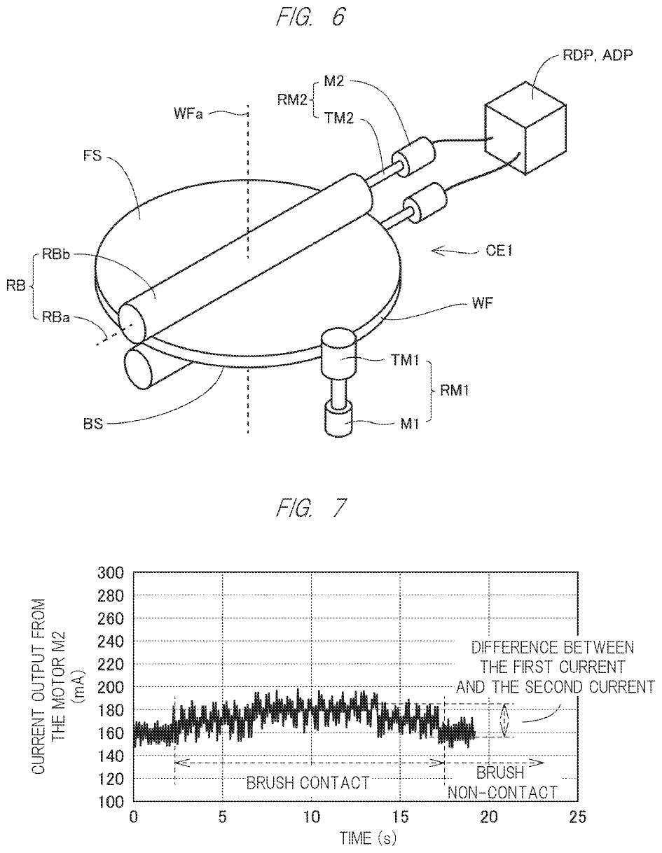

In the chemical mechanical polishing step S4, as shown in FIG. 5, the conductive material CM protruding from the contact hole CH is removed by chemical mechanical polishing (CMP). As a result, the contact plug CP is formed in the contact hole CH.

In the cleaning step S5, the semiconductor wafer WF is cleaned. The cleaning steps S5 includes a cleaning apparatus preparation step S51, a semiconductor wafer rotation step S52, and a brush rotation step S53. In the cleaning apparatus preparation step S51, the cleaning apparatus CE1 is prepared. As shown in FIG. 6, the cleaning apparatus CE1 includes a rotation mechanism RM1, a rotation mechanism RM2, a roller brush RB, a rotation detector RDP, and an abnormality detector ADP.

The roller brush RB has, for example, a cylindrical shape. The roller brush RB has a central axis RBa and an outer peripheral surface RBb. The roller brushes RB are formed of, for example, Polyvinyl Alcohol (PVA) sponges or the like. The roller brush RB is configured to be capable of contacting and separating from the front surface FS.

The rotation mechanism RM1 includes a motor M1 and a transmission mechanism TM1, and the rotation mechanism RM2 includes a motor M2 and a transmission mechanism TM2. The transmission mechanism TM1 and the transmission mechanism TM2 are composed of, for example, mechanical parts such as belts and gears.

The number of the rotation mechanisms RM2 and the number of the roller brushes RB may be 2. In this case, one roller brush RB is disposed on the front surface FS side of the semiconductor wafer WF, and the other roller brush RB is disposed on the back surface BS side of the semiconductor wafer WF.

In the semiconductor wafer rotation step S52, the semiconductor wafer WF is rotated around the center axis WFa by the rotation mechanism RM1. More specifically, the rotation of the motor M1 is transmitted to the semiconductor wafer WF via the transmission mechanism TM1, whereby the semiconductor wafer WF is rotated around the center axis WFa. The center axis WFa is perpendicular to the front surface FS and the back surface BS.

In the brush rotation step S53, the roller brush RB is rotated around the center axis RBa by the rotation mechanism RM2. More specifically, the rotation of the motor M2 is transmitted to the roller brush RB via the transmission mechanism TM2, whereby the roller brush RB is rotated around the center axis RBa. The rotation speed of the roller brush RB is detected by the rotation detector RDP.

The semiconductor wafer WF is cleaned by contacting the outer peripheral surface RBb with the front surface FS (back surface BS) in a state in which the semiconductor wafer WF and the roller brush RB are rotated. Specifically, the slurry and the like used in the chemical mechanical polishing step S4 are removed by this cleaning.

The motor M2 outputs a current (first current) to the abnormality detector ADP in a state in which the outer peripheral surface RBb and the front surface FS (back surface BS) are separated from each other. In addition, the motor M2 outputs a current (second current) to the abnormality detector ADP in a state in which the outer peripheral surface RBb and the front surface FS (back surface BS) are in contact with each other.

The abnormality detector ADP detects the rotation abnormality of the rotation mechanism RM2 based on the current output from the motor M2. More specifically, first, the abnormality detector ADP calculates a difference between the first current and the second current. Secondly, the abnormality detector ADP detects the rotation abnormality of the rotation mechanism RM2 by comparing the difference between the first current and the second current with a predetermined threshold value, i.e., by determining whether the difference between the first current and the second current exceeds the threshold value. The abnormality detector ADP is composed of, for example, a current sensor provided in a cable connecting the motor M2 and the motor driver, a microcontroller connected to the current sensor, and the like.

The threshold value is set based on, for example, the rotation speed of the roller brush RB detected by the rotation detector RDP. Preferably, in case of the rotation speed of the roller brush RB is 100 revolutions per minute, the threshold value is set to 1.5 times or more and 3.0 times or less of the difference between the first current and the second current when the rotation mechanism RM2 is normal. Preferably, in case of the rotation speed of the roller brush RB is 200 revolutions per minute, the threshold value is set to 2.5 times or more and 3.0 times or less of the difference between the first current and the second current when the rotation mechanism RM2 is normal.

The threshold may be compared to a difference between the average value of the first current and the average value of the second current. The threshold may be compared to a difference between the maximum value of the first current and the maximum value of the second current. The threshold may be compared to a difference between the Fourier transform value of the first current and the Fourier transform value of the second current.

The abnormality detector ADP may detect an abnormality of the rotation mechanism RM2 by comparing the second current output from the motor M2 with a predetermined threshold value, i.e., by determining whether the second current exceeds the threshold value.

In the above description, the abnormality detection of the rotation mechanism RM2 when the semiconductor wafer WF is cleaned after the contact plug CP is formed has been described. However, the abnormality detection method described above can be applied to the abnormality detection of the rotation mechanism RM2 when other cleaning is performed. In this case, different thresholds may be set for the recipes used for each cleaning step.

In the above description, the abnormality detection of the rotation speed of the semiconductor wafer WF has been described. However, the abnormality detection method described above can be applied to other than the abnormality detection for the rotation speed of the semiconductor wafer WF. For example, when the roller brush RB is damaged, the torque of the motor M2 rises and the second current rises accordingly, so that the abnormality detection method described above can be applied to the damage detection of the roller brush RB.

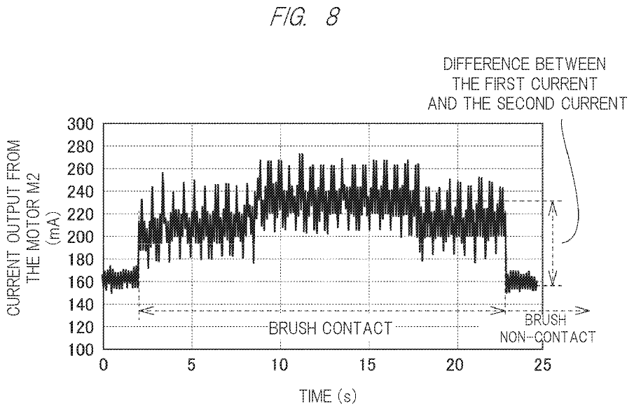

Hereinafter, effects of the method of manufacturing the semiconductor device according to the first embodiment will be described. As shown in FIG. 7, when the rotation mechanism RM1 is normal, the difference between the first current and the second current is relatively small. On the other hand, as shown in FIG. 8, when there is an abnormality in the rotation mechanism RM1, that is, when the rotation of the semiconductor wafer WF is stopped or the rotation speed of the semiconductor wafer WF is lowered, the difference between the first current and the second current becomes relatively large. Therefore, in the manufacturing method of the semiconductor device according to the first embodiment, it is possible to detect whether the semiconductor wafer WF is normally rotated in the cleaning step S5 by monitoring the current output from the motor M2.

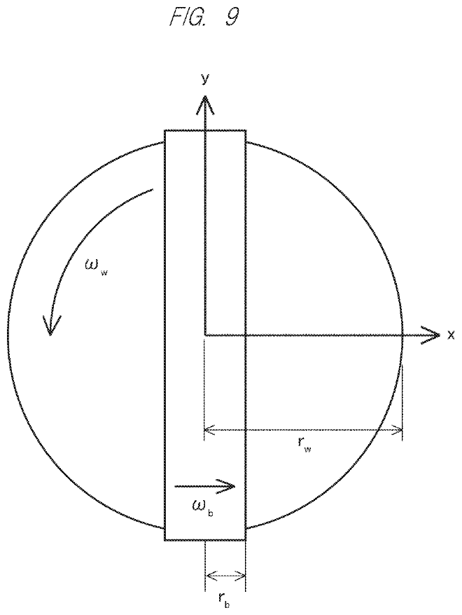

In general, the magnitude of the frictional force exerted when two objects are in contact with each other is independent of their relative velocity, but the direction of the frictional force is in the direction of their relative velocity. As shown in FIG. 9, it is assumed that the front surface FS of the semiconductor wafer WF is an xy plane, and the outer peripheral surface RBb of the roller brush RB is in contact with the front surface FS on the y-axis.

Let ω_{w} be the angular velocity of rotation about the central axis WFa of the semiconductor wafer WF, ω_{b} be the angular velocity of rotation about the central axis RBa of the roller brush RB, r_{w} be the radius of the semiconductor wafer WF, and r_{b} be the radius of the roller brush RB. If the rotational speed of the roller brush RB around the central axis RBa at the point (0, y) at which the wafer WF contacts the roller brush RB is v_{b}, then v_{b}=r_{b}×ω_{b}. If the rotational speed of the semiconductor wafer WF around the center axis WFa at the point (0, y) at which the semiconductor wafer WF contacts the roller brush RB is represented by v_{w}, v_{w} becomes y×ω_{w}.

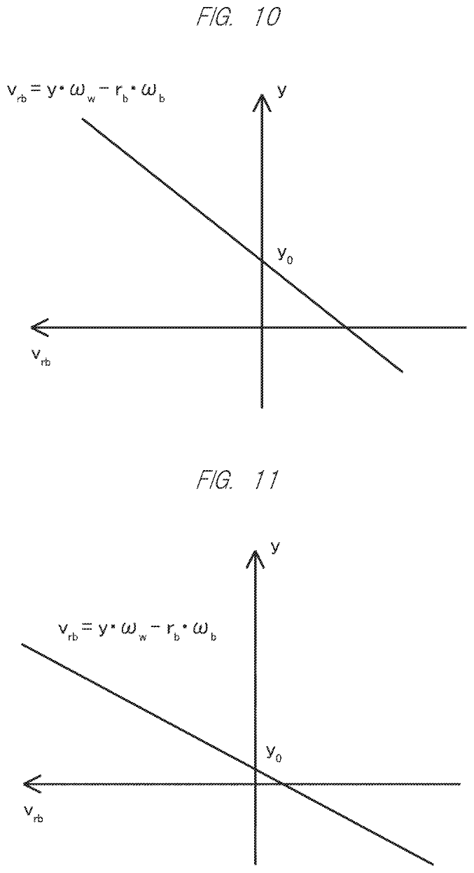

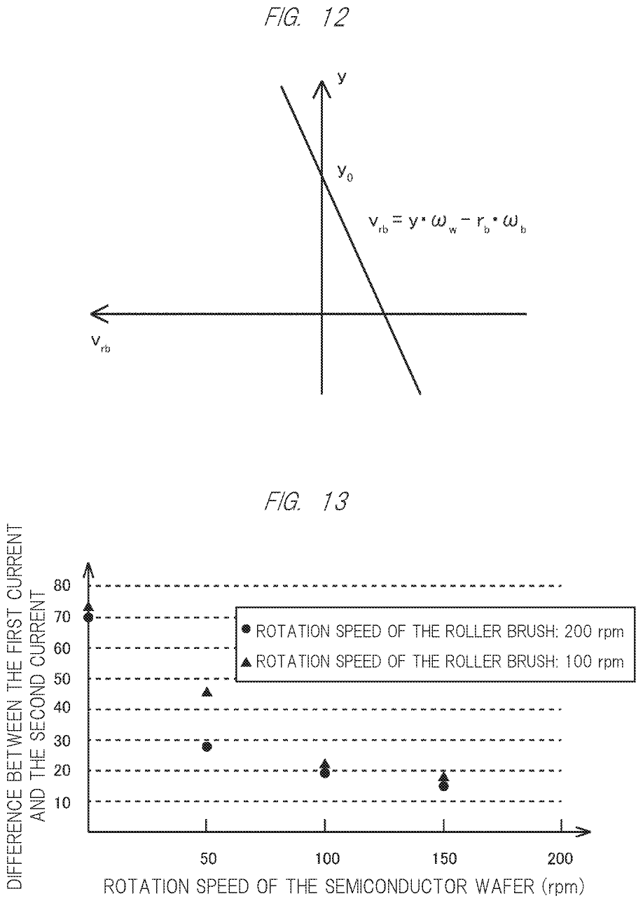

Therefore, when the relative velocity of the semiconductor wafer WF viewed from the roller brush RB side is v_{rb}, the relative velocity of the semiconductor wafer WF is v_{rb}=y×ω_{w}−r_{b}×ω_{b}. In this equation, when v_{rb} is set to 0 and y₀, which is a position where the relative velocity of the semiconductor wafer WF as viewed from the roller brush RB becomes 0, is obtained, y₀ is set to r_{b}×ω_{b}/ω_{w}. This is shown in FIG. 10.

As described above, since the direction of the frictional force acting when two objects touch each other is determined by the direction of the relative velocity, the direction of the frictional force changes with respect to the y=y₀. The torque acting on the roller brush RB is the sum of the torques acting at each point on the y-axis. Torques acting in opposite directions about the y₀ cancel each other out.

As shown in FIG. 11, as the rotational velocity of the semiconductor wafer WF increases (the value of ω_{w} increases), the position of the semiconductor wafer WF in the y₀ approaches the origin. That is, as the rotation speed of the semiconductor wafer WF increases, the torque acting on the roller brush RB decreases. On the other hand, as shown in FIG. 12, when the rotational velocity of the semiconductor wafer WF decreases, (the value of ω_{w} decreases), the position of the semiconductor wafer WF in the y₀ moves away from the origin on the y-axis. That is, when the rotation speed of the semiconductor wafer WF is reduced, the torques acting in the opposite directions are less likely to cancel each other out, and the torque acting on the roller brush RB is increased.

The current output from the motor M2 increases as the torque acting on the roller brush RB increases. Therefore, when an abnormality occurs in the rotation mechanism RM1, the torque acting on the roller brush RB increases due to the abnormality, and the current output from the motor M2 increases. Therefore, in the manufacturing method of the semiconductor device according to the first embodiment, it is possible to detect whether the semiconductor wafer WF is normally rotated in the cleaning step S5 by monitoring the current output from the motor M2.

As shown in FIG. 13, the dependence of the difference between the first current and the second current on the rotation speed of the semiconductor wafer WF changes depending on the rotation speed of the roller brush RB. Therefore, the threshold value to be compared with the difference between the first current and the second current is set based on the rotation speed of the roller brush RB, so that it is possible to more accurately detect whether the semiconductor wafer WF is rotating normally in the cleaning step S5.

If the rotation speed of the roller brush RB is 100 revolutions per minute, the difference between the first current and the second current when the rotation speed of the semiconductor wafer WF is 50 revolutions per minute is about 1.5 times the difference between the first current and the second current when the rotation speed of the semiconductor wafer WF is 100 revolutions per minute (i.e., when the rotation mechanism RM1 is normal). When the rotation speed of the roller brush RB is 100 revolutions per minute, the difference between the first current and the second current when the rotation speed of the semiconductor wafer WF is stopped is about 3.3 times the difference between the first current and the second current when the rotation speed of the semiconductor wafer WF is 100 revolutions per minute. Therefore, when the rotation speed of the roller brush RB is 100 revolutions per minute, it is possible to sufficiently detect the abnormality of the rotation mechanism RM2 by setting the threshold value to 1.5 times or more and 3.0 times or less of the difference between the first current and the second current when the rotation mechanism RM1 is normal.

Similarly, if the rotation speed of the roller brush RB is 200 revolutions per minute, it is possible to sufficiently detect the abnormality of the rotation mechanism RM2 by setting the threshold value to 2.5 times or more and 3.0 times or less of the difference between the first current and the second current when the rotation mechanism RM1 is normal.

### Second Embodiment

The method of manufacturing a semiconductor device according to the second embodiment will be described below.

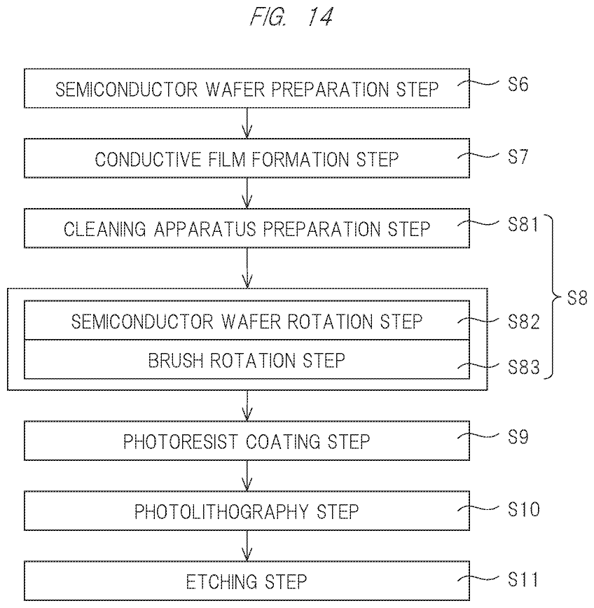

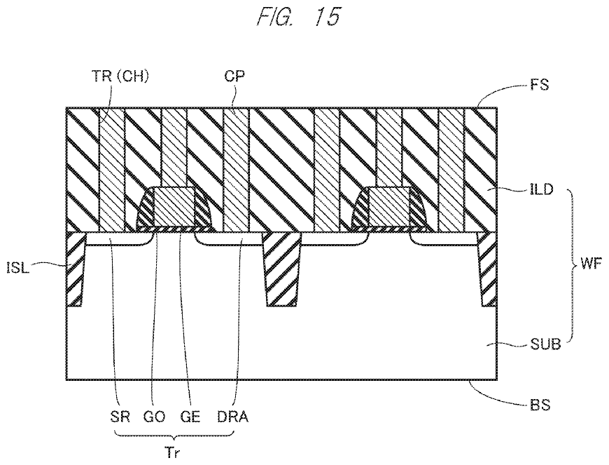

As shown in FIG. 14, the method of manufacturing a semiconductor device according to the second embodiment includes a semiconductor wafer preparation step S6, a conductive film formation step S7, a cleaning step S8, a photoresist coating step S9, a photolithography step S10, and an etching step S11.

As shown in FIG. 15, in the semiconductor wafer preparation step S6, a semiconductor wafer WF is prepared. The semiconductor wafer WF has a semiconductor substrate SUB and an interlayer insulating film ILD. The interlayer insulating film ILD is formed on the surface FS of the semiconductor wafer WF. A contact plug CP is formed in the interlayer insulating film ILD.

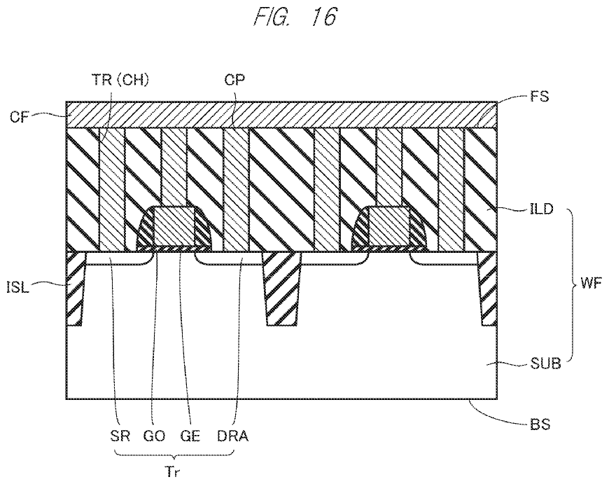

In the conductive film forming step S7, as shown in FIG. 16, a conductive film CF is formed. The conductive film CF is formed of, for example, aluminum (Al), an aluminum alloy, or the like. The conductive film CF is formed by, for example, sputtering or the like.

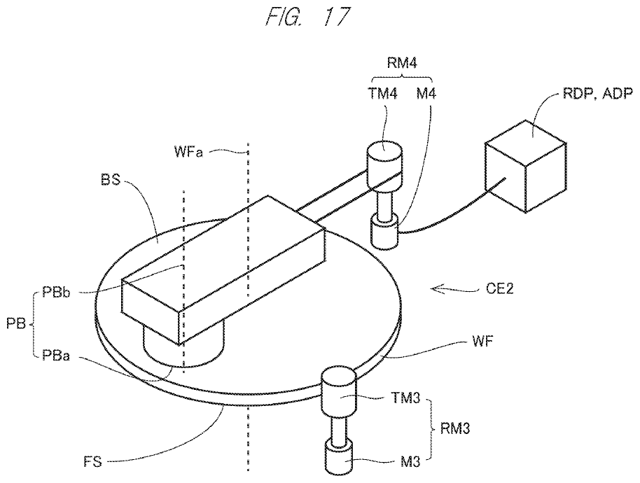

In the cleaning step S8, the semiconductor wafer WF is cleaned. The cleaning step S8 includes a cleaning apparatus preparation step S81, a semiconductor wafer rotation step S82, and a brush rotation step S83. In the cleaning apparatus preparation step S81, the cleaning apparatus CE2 is prepared. As shown in FIG. 17, the cleaning device CE2 includes a rotation mechanism RM3, a rotation mechanism RM4, a pen-type brush PB, and an abnormality detector ADP. The rotation mechanism RM3 includes a motor M3 and a transmission mechanism TM3, and the rotation mechanism RM4 includes a motor M4 and a transmission mechanism TM4. The transmission mechanism TM3 and the transmission mechanism TM4 are composed of, for example, mechanical parts such as belts and gears.

The pen-type brush PB has, for example, a cylindrical shape. The pen-type brush PB has a center axis PBa and an end surface PBb. The end face PBb is perpendicular to the center axis PBa. The pen-type brush PB is formed of, for example, PVA sponge or the like. The pen-type brush PB is configured to be able to contact and separate from the back surface BS.

In the semiconductor wafer rotation step S82, the semiconductor wafer WF is rotated around the center axis WFa by the rotation mechanism RM3. More specifically, the rotation of the motor M3 is transmitted to the semiconductor wafer WF via the transmission mechanism TM3, whereby the semiconductor wafer WF is rotated around the center axis WFa. In the brush rotation process S83, the pen-type brush PB is rotated around the center axis PBa by the rotation mechanism RM4. More specifically, the rotation of the motor M4 is transmitted to the pen-type brush PB via the transmission mechanism TM4, whereby the pen-type brush PB is rotated around the center axis PBa. The rotation speed of the pen-type brush PB is detected by the rotation detector RDP.

The cleaning of the semiconductor wafer WF is performed by the contact between the end surface PBb and the back surface BS in a state in which the semiconductor wafer WF and the pen-type brush PB are rotated. By removing foreign matter adhering to the back surface BS by this cleaning, defocus error in the photolithography step S10 is suppressed.

The motor M4 outputs a third current to the abnormality detector ADP in a state in which the end surface PBb and the back surface BS are separated from each other. The motor M4 outputs a fourth current to the abnormality detector ADP while the end surface PBb and the back surface BS are in contact with each other.

The abnormality detector ADP detects the rotation abnormality of the rotation mechanism RM4 based on the current output from the motor M4. More specifically, first, the abnormality detector ADP calculates a difference between the third current and the fourth current. Second, the abnormality detector ADP detects the rotation abnormality of the rotation mechanism RM4 by comparing the difference between the third current and the fourth current with a predetermined threshold value, i.e., by determining whether the difference between the third current and the fourth current exceeds the threshold value.

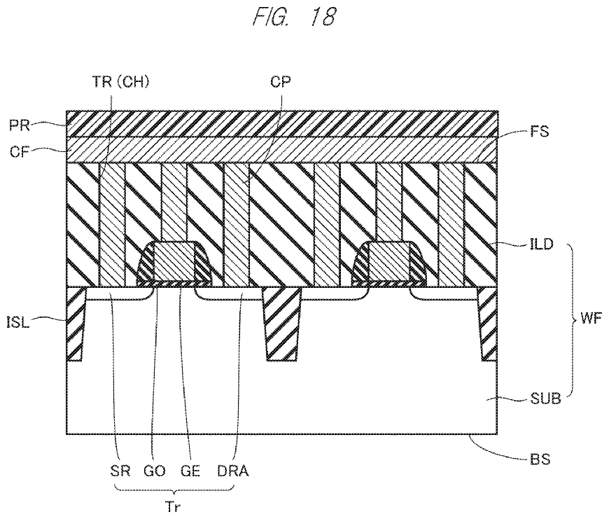

In the photoresist coating step S9, as shown in FIG. 18, a photoresist PR is formed. The photoresist PR is formed on the conductive film CF. The photoresist PR is applied, for example, by spin coating.

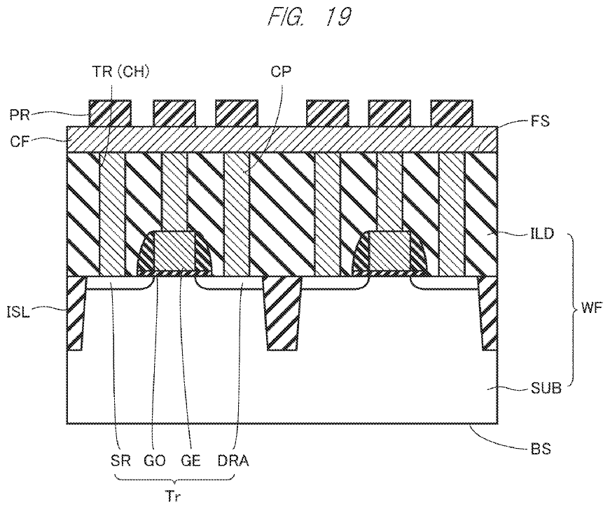

In the photolithography step S10, as shown in FIG. 19, the photoresist PR is patterned by photolithography. Specifically, after exposing the photoresist PR in the portion where the opening is to be formed by using the photomask, the photoresist PR is developed.

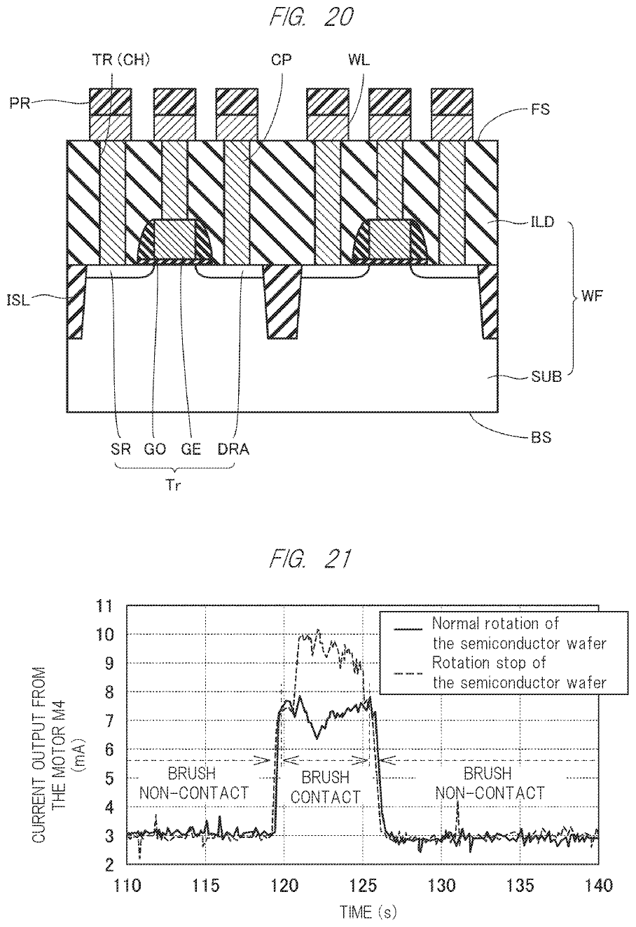

In the etching step S11, as shown in FIG. 20, the conductive film CF is etched. This etching is performed using the photoresist PR patterned in the photolithography step S10 as a mask. This etching is, for example, anisotropic etching such as RIE. In the etching step S11, the conductive film CF is patterned to form the wiring WL electrically connected to the contact plug CP.

In the above description, the abnormality detection of the rotation speed of the semiconductor wafer WF has been described. However, the abnormality detection method described above can be applied to other than the abnormality detection for the rotation speed of the semiconductor wafer WF. For example, when the belt for transmitting power to the pen-type brush PB is cut and wound around the motor M4, the torque of the motor M4 rises and the fourth current rises accordingly, so that the abnormality detection method described above can be applied to the detection of the damage of the transmission mechanism TM4.

Hereinafter, effects of the method of manufacturing the semiconductor device according to the second embodiment will be described. As shown in FIG. 21, when the rotation mechanism RM4 is normal, the difference between the third current and the fourth current is relatively small. On the other hand, when there is an abnormality in the rotation mechanism RM4, that is, when the rotation of the semiconductor wafer WF is stopped or the rotation speed of the semiconductor wafer WF is lowered, the difference between the third current and the fourth current becomes relatively large. Therefore, in the manufacturing method of the semiconductor device according to the second embodiment, it is possible to detect whether the semiconductor wafer WF is normally rotated in the cleaning step S8 by monitoring the current output from the motor M4.

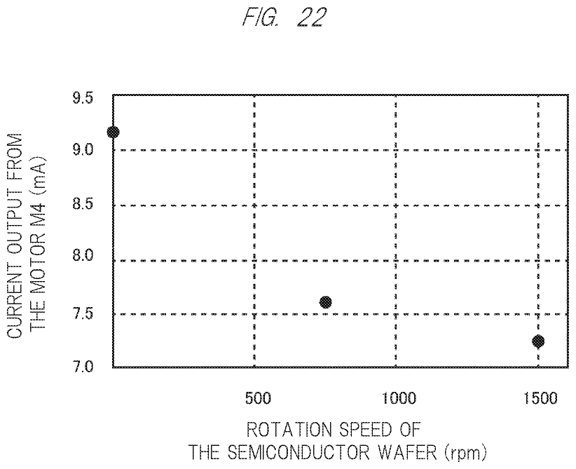

As shown in FIG. 22, in case of the rotation speed of the pen-type brush PB is 670 revolutions per minute, the fourth current when the semiconductor wafer WF is normally rotated (when the rotation speed of the semiconductor wafer WF is 1500 revolutions per minute) is approximately 1.2 times the fourth current when there is an abnormality in the rotation of the semiconductor wafer WF (when the rotation of the semiconductor wafer WF is stopped). Therefore, for example, if the rotation speed of the pen-type brush PB is 670 revolutions per minute, when the abnormality of the rotation mechanism RM4 is detected based on whether the fourth current exceeds a predetermined threshold value, the abnormality of the rotation mechanism RM4 can be detected by setting the threshold value to 1.2 times or more of the fourth current when the rotation mechanism RM4 is normal.

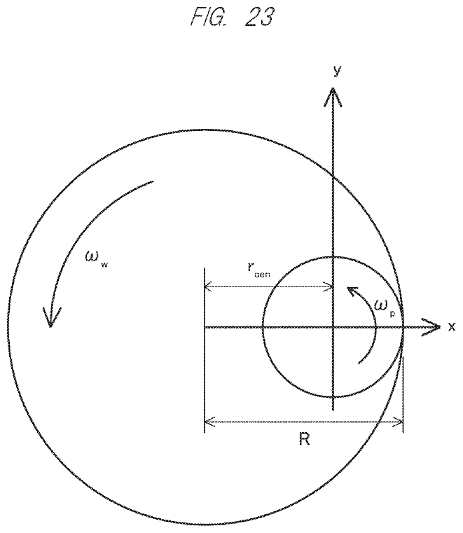

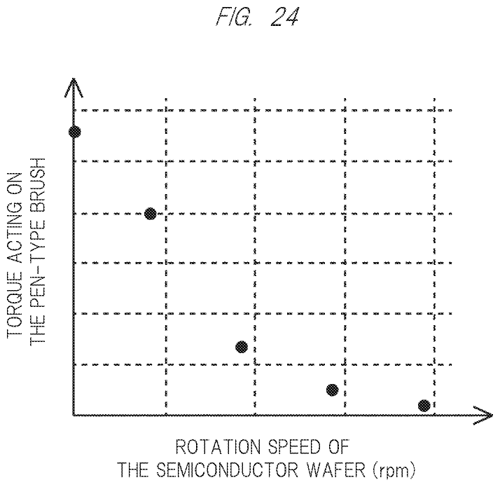

As shown in FIG. 23, the angular velocity of rotation about the central axis WFa of the semiconductor wafer WF is ω_{w}, the angular velocity of rotation about the central axis PBa of the pen-type brush PB is ωₚ, the radius of the semiconductor wafer WF is R, the distance between the center of the pen-type brush PB and the center of the semiconductor wafer WF is r_{cen}, the torque acting on the pen-type brush PB is i, and the proportionality constant is P. The torque acting on the pen brush PB is calculated by the following equation.

$$\vec{τ} = ∮ \frac{( {ω}_{p} - {ω}_{w} ) ( {x}^{2} + {y}^{2} ) + {r}_{cen} {ω}_{p} x}{\sqrt{{( {ω}_{p} - {ω}_{w} )}^{2} ( {x}^{2} + {y}^{2} ) + {r}_{cen}^{2} {ω}_{p}^{2} + 2 ( {ω}_{p} - {ω}_{w} ) {r}_{cen} {ω}_{p} x}} \cdot P \qquad [ Equation 1 ]$$

The relationship between the rotation speed of the semiconductor wafer WF and the torque acting on the pen-type brush PB is simulated based on the above equation as shown in FIG. 24. As shown in FIG. 24, as the rotational speed of the semiconductor wafer WF decreases, the torque acting on the pen-type brush PB increases. As described above, when an abnormality occurs in the rotation mechanism RM4, the torque acting on the pen-type brush PB increases due to the abnormality, and the current output from the motor M4 increases. Therefore, in the manufacturing method of the semiconductor device according to the second embodiment, it is possible to detect whether the semiconductor wafer WF is normally rotated in the cleaning step S8 by monitoring the current output from the motor M4.

### Third Embodiment

The method of manufacturing a semiconductor device according to a third embodiment will be described below. Incidentally, differences from the manufacturing method of the semiconductor device according to the first embodiment will be described, and an overlapping description will not be repeated.

The method of manufacturing a semiconductor device according to the third embodiment includes a semiconductor wafer preparation step S1, a groove formation step S2, a conductive material embedding step S3, a chemical mechanical polishing step S4, and a cleaning step S5. The cleaning step S5 includes a cleaning apparatus preparation step S51, a semiconductor wafer rotation step S52, and a brush rotation step S53. In these points, the manufacturing method of the semiconductor device according to the third embodiment is common to the manufacturing method of the semiconductor device according to the first embodiment.

However, the manufacturing method of the semiconductor device according to the third embodiment differs from the manufacturing method of the semiconductor device according to the first embodiment in the details of the groove forming process S2, the conductive material embedding step S3, the chemical mechanical polishing step S4, and the cleaning step S5.

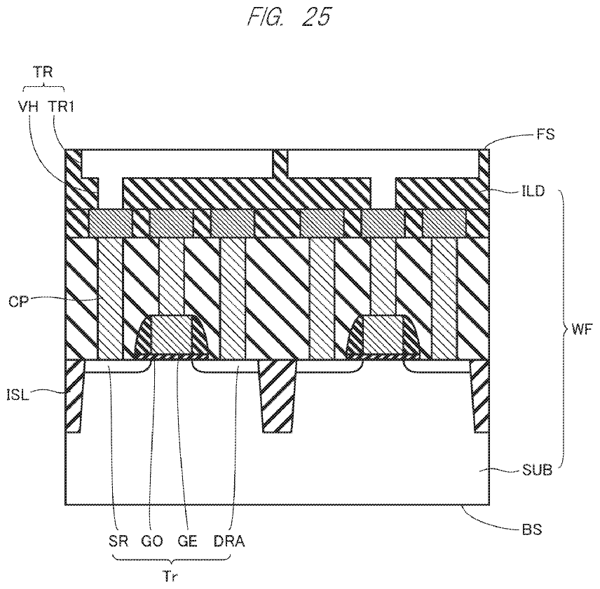

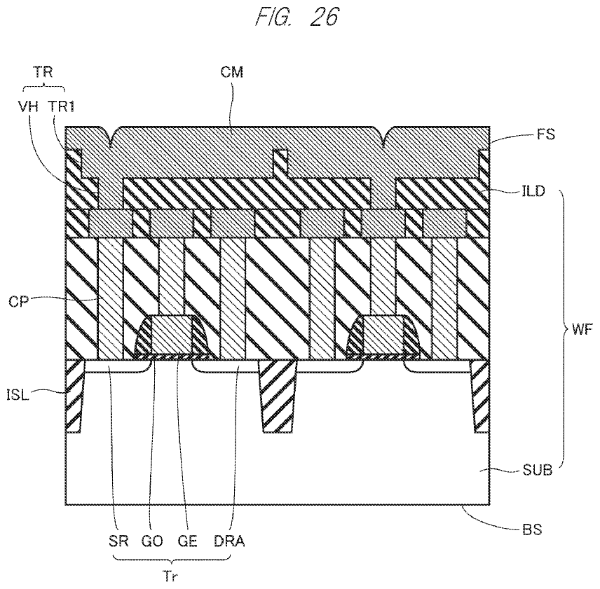

In the groove forming step S2, as shown in FIG. 25, the wiring groove TR1 and the via hole VH are formed as the groove TR. The wiring groove TR1 and the via hole VH are formed by anisotropic etching such as RIE.

In the conductive material embedding step S3, as shown in FIG. 26, the conductive material CM is embedded in the wiring groove TR1 and the via hole VH. As the conductive material CM, a material containing copper (Cu) is used. The conductive material CM is embedded in the wiring groove TR1 and the via hole VH by forming a seed layer on the surfaces of the wiring groove TR1 and the via hole VH and performing electrolytic plating using the seed layer. Although not shown in the figure, a barrier metal such as titanium nitride (TiN) is formed on the surfaces of the wiring groove TR1 and the via hole VH after the groove forming step S2 and before the conductive material filling step S3 is performed.

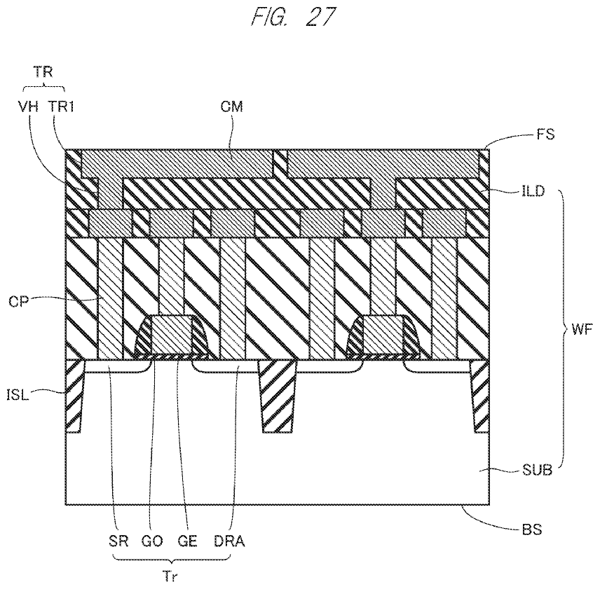

In the chemical mechanical polishing step S4, as shown in FIG. 27, the protruding portion of the conductive material CM from the wiring groove TR1 and the via hole VH is removed by chemical mechanical polishing (CMP).

The chemical mechanical polishing step S4 and the cleaning step S5 are performed in a state of light shielding. “The chemical mechanical polishing step S4 and the cleaning step S5 are performed in a state of light” means that the chemical mechanical polishing step S4 and the cleaning step S5 are performed in a chamber having an illuminance of 100 lux or less.

Although an example in which the roller brush RB is used as the brush for performing the cleaning step S5 is described above, the brush for performing the cleaning step S5 may be the pen-type brush PB.

Hereinafter, effects of the method for manufacturing a semiconductor device according to the third embodiment will be described. Incidentally, differences from the effect of the manufacturing method of the semiconductor device according to the first embodiment will be described, and an overlapping description will not be repeated.

In case of the conductive material CM is a material containing copper, in order to prevent corrosion of the conductive material CM, it is necessary to perform the chemical mechanical polishing step S4 and the cleaning step S5 in a state of light shielding. However, when the chemical mechanical polishing step S4 and the cleaning step S5 are performed in a state of light shielding, it is difficult to detect the rotation of the semiconductor wafer WF by an optical method, for example, a method using a photoelectric sensor.

On the other hand, in the manufacturing method of the semiconductor device according to the third embodiment, since the rotation of the semiconductor wafer WF is detected by monitoring the current output from the motor M2, the rotation of the semiconductor wafer WF can be detected even in an environment in which it is difficult to detect the rotation of the semiconductor wafer WF by an optical method.

### Fourth Embodiment

The method of manufacturing a semiconductor device according to a fourth embodiment will be described below. Incidentally, differences from the manufacturing method of the semiconductor device according to the first embodiment will be described, and an overlapping description will not be repeated.

The method of manufacturing a semiconductor device according to the fourth embodiment includes a semiconductor wafer preparation step S1, a groove formation step S2, a conductive material embedding step S3, a chemical mechanical polishing step S4, and a cleaning step S5. The cleaning step S5 includes a cleaning apparatus preparation step S51, a semiconductor wafer rotation step S52, and a brush rotation step S53. In these points, the manufacturing method of the semiconductor device according to the fourth embodiment is common to the manufacturing method of the semiconductor device according to the first embodiment.

However, the manufacturing method of the semiconductor device according to the fourth embodiment differs from the manufacturing method of the semiconductor device according to the first embodiment in that an abnormality of rotation of the roller brush RB is detected.

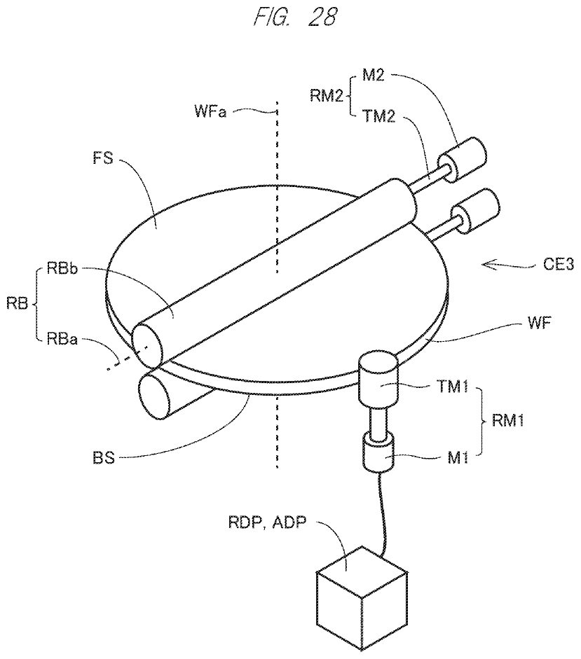

As shown in FIG. 28, in the cleaning device CE3, the motor M1 outputs a fifth current to the abnormality detector ADP in a state in which the outer peripheral surface RBb and the front surface FS (back surface BS) are separated from each other. The motor M1 outputs a sixth current to the abnormality detector ADP in a state in which the outer peripheral surface RBb and the front surface FS (back surface BS) are in contact with each other.

The abnormality detector ADP detects the rotation abnormality of the rotation mechanism RM2 based on the current output from the motor M1. More specifically, first, the abnormality detector ADP calculates a difference between the fifth current and the sixth current. Second, the abnormality detector ADP detects the rotation abnormality of the rotation mechanism RM2 by comparing the difference between the fifth current and the sixth current with a predetermined threshold value (by determining whether the difference between the fifth current and the sixth current exceeds the threshold value).

Although an example in which the roller brush RB is used as the brush for performing the cleaning step S5 has been described above, the brush for performing the cleaning step S5 may be the pen-type brush PB.

Although the abnormality detection of the rotation speed of the roller brush RB has been described above, the abnormality detection method can be applied to other than the abnormality detection of the rotation speed of the roller brush RB. For example, when there is a problem in the lowering operation of the roller brush RB, since the roller brush RB and the semiconductor wafer WF do not come into contact with each other, the torque of the motor M1 decreases and the sixth current decreases accordingly, so that the abnormality detection method described above can be applied to the detection of the abnormality in contact between the roller brush RB and the semiconductor wafer WF.

Hereinafter, effects of the method for manufacturing a semiconductor device according to the fourth embodiment will be described. Incidentally, differences from the effect of the manufacturing method of the semiconductor device according to the first embodiment will be described, and an overlapping description will not be repeated.

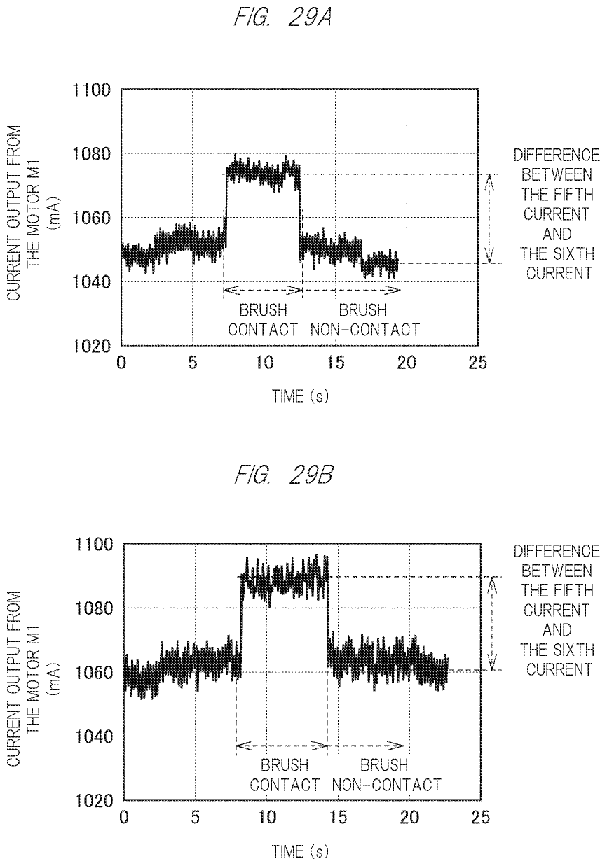

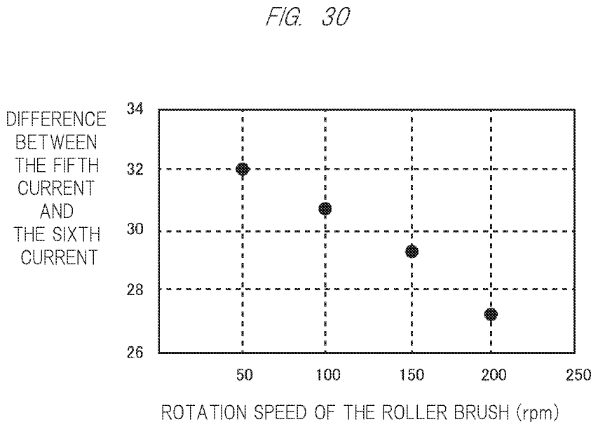

As shown in FIG. 29, when the rotation mechanism RM2 is normal, the difference between the fifth current and the sixth current is relatively small. On the other hand, as shown in FIG. 29, when there is an abnormality in the rotation mechanism RM2, that is, when the rotation of the roller brush RB is stopped or the rotation speed of the roller brush RB is lowered, the difference between the fifth current and the sixth current becomes relatively large. Therefore, according to the manufacturing method of the semiconductor device according to the fourth embodiment, it is possible to detect whether the roller brush RB is normally rotating in the cleaning step S5 by monitoring the current output from the motor M1.

As shown in FIG. 30, when the rotation speed of the semiconductor wafer WF is 100 revolutions per minute, the difference between the fifth current and the sixth current when the roller brush RB is normally rotating (when the rotation speed of the roller brush RB is 200 revolutions per minute) is about 1.15 times the difference between the fifth current and the sixth current when there is an abnormality in the rotation of the roller brush RB (when the rotation of the roller brush RB is stopped). Therefore, for example, if the rotation speed of the semiconductor wafer WF is 100 revolutions per minute, it is possible to detect the abnormality of the rotation mechanism RM1 by setting the threshold value to be compared with the difference between the fifth current and the sixth current to 1.15 times or more the difference between the fifth current and the sixth current when the rotation mechanism RM1 is normal.

The invention made by the present inventors was specifically described according to the foregoing embodiments. Obviously, the present invention is not limited to the foregoing embodiments and can be changed in various ways within the scope of the invention.

What is claimed is:

1. A method of manufacturing a semiconductor device, comprising the steps of:
preparing a semiconductor wafer having a front surface and a first central axis perpendicular to the front surface, and having an interlayer insulating film formed on the front surface;
forming a groove in the interlayer insulating film;
embedding a conductive material into the groove;
removing a protruding part of the conductive material protruding from the groove by chemical mechanical polishing; and
cleaning the semiconductor wafer, wherein
in the cleaning the semiconductor wafer includes the steps of:
preparing a cleaning apparatus having a roller brush having a first rotation mechanism by a first motor, a second rotation mechanism by a second motor, a second central axis, an outer peripheral surface,
rotating the semiconductor wafer around the first central axis by the first rotation mechanism, and
rotating the roller brush around the second central axis and contacting the outer peripheral surface with the front surface by the second rotation mechanism,
and,
an abnormality in the cleaning step is detected based on an electric current from the second motor.

2. A method of manufacturing a semiconductor device according to the claim 1, wherein
the abnormality in the cleaning step is abnormality of the second rotation mechanism.

3. A method of manufacturing a semiconductor device according to the claim 2, wherein
the abnormality of the second rotation mechanism is detected by comparing a threshold value with a difference value that is a difference of the electric current from the second motor between in a state that the outer peripheral surface is separated from the front surface and in a state that the outer peripheral surface is contacted with the front surface.

4. A method of manufacturing a semiconductor device according to the claim 3, wherein
the cleaning apparatus further has a rotation detector which detects rotation speed of the roller brush, and
the threshold value is set based on the rotation speed.

5. A method of manufacturing a semiconductor device according to the claim 4, wherein
when the rotation speed is 100 revolutions per minute,
the second rotation mechanism is normality,
in the state that the outer peripheral surface is separated from the front surface, the electric current from the second motor and the second rotation mechanism are normality,
in the state that the outer peripheral surface is contacted with the front surface, the threshold value is set 1.5 times or more to 3.0 times or less of the difference value of the electric current from the second motor.

6. A method of manufacturing a semiconductor device according to the claim 4, wherein
when the rotation speed is 200 revolutions per minute,
the second rotation mechanism is normality,
in the state that the outer peripheral surface is separated from the front surface, the electric current from the second motor and the second rotation mechanism are normality,
in the state that the outer peripheral surface is contacted with the front surface, the threshold value is set 2.5 times or more to 3.0 times or less of the difference value of the electric current from the second motor.

7. A method of manufacturing a semiconductor device according to the claim 2, wherein
the abnormality of the second rotation mechanism is detected by comparing a threshold value with a difference value that is a difference of an average of the electric current from the second motor between in a state that the outer peripheral surface is separated from the front surface and in a state that the outer peripheral surface is contacted with the front surface.

8. A method of manufacturing a semiconductor device according to the claim 2, wherein
the abnormality of the second rotation mechanism is detected by comparing a threshold value with a difference value that is a difference of a maximum of the electric current from the second motor between in a state that the outer peripheral surface is separated from the front surface and in a state that the outer peripheral surface is contacted with the front surface.

9. A method of manufacturing a semiconductor device according to the claim 2, wherein
the abnormality of the second rotation mechanism is detected by comparing a threshold value with a difference value that is a difference of a Fourier transform value of the electric current from the second motor between in a state that the outer peripheral surface is separated from the front surface and in a state that the outer peripheral surface is contacted with the front surface.

10. A method of manufacturing a semiconductor device according to the claim 2, wherein
the conductive material includes copper, and
the removing step and the cleaning step are performed in a state of light shielding from the circumferences.

11. A method of manufacturing a semiconductor device, comprising the steps of:
preparing a semiconductor wafer having a front surface, a back surface opposite to the front surface, and a first central axis perpendicular to the front surface and the back surface, and having an interlayer insulating film formed on the front surface;
forming a conductive material on the interlayer insulating film,
after forming the conductive material, cleaning the semiconductor wafer; and
after cleaning the semiconductor wafer, forming a photoresist, wherein,
the cleaning step including the steps of:
preparing a cleaning apparatus having a pen-type brush having a first rotation mechanism by a first motor, a second rotation mechanism by a second motor, a second central axis, and an end face perpendicular to the second central axis rotating the semiconductor wafer around the first central axis by the first rotation mechanism, and
rotating the pen-type brush around the second central axis and contacting the end face with the front surface by the second rotation mechanism,
and,
an abnormality in the cleaning step is detected based on an electric current from the second motor.

12. A cleaning apparatus, comprising:
a first rotation mechanism having a first motor and rotating the semiconductor wafer around the first central axis perpendicular to the front surface;
a roller brush having a second central axis and an outer peripheral surface and configured so as to be capable of the outer peripheral surface contacting with and separating from the front surface;
a second rotation mechanism having a second motor and rotating the roller brush around the second central axis; and
an abnormality detector detecting abnormality of the second rotation mechanism based on an electric current from the second motor, wherein
the abnormality detector is configured so as to be detect the abnormality of the second rotation mechanism by comparing a threshold value with a difference value that is a difference of the electric current from the second motor between in a state that the outer peripheral surface is separated from the front surface and in a state that the outer peripheral surface is contacted with the front surface.

13. A cleaning apparatus, comprising:
a first rotation mechanism having a first motor and rotating the semiconductor wafer around the first central axis perpendicular to the front surface;
a pen-type brush having a second central axis and an end face perpendicular to the second central axis and configured so as to be capable of the end face contacting with and separating from the front surface;
a second rotation mechanism having a second motor and rotating the pen-type brush around the second central axis; and
an abnormality detector detecting abnormality of the second rotation mechanism based on an electric current from the second motor, wherein
the abnormality detector is configured so as to be detect the abnormality of the second rotation mechanism by comparing a threshold value with a difference value that is a difference of the electric current from the second motor between in a state that the end face is separated from the front surface and in a state that the end face is contacted with the front surface.
